(19) United States
(12) Patent Application Publication
(10) Pub. No.: US 2026/0341221 A1
(43) Pub. Date: Oct. 29, 2026

(54) DISPLAY PANEL AND DISPLAY DEVICE

(71) Applicants: CHENGDU BOE OPTOELECTRONICS TECHNOLOGY CO., LTD., CHENGDU, SICHUAN (CN); BOE TECHNOLOGY GROUP CO., LTD., BEIJING (CN); BEIJING BOE TECHNOLOGY DEVELOPMENT CO., LTD., BEIJING (CN)

(72) Inventors: YU WU, BEIJING (CN); XIANGFEI HE, BEIJING (CN); LIQIANG CHEN, BEIJING (CN); XING YAO, BEIJING (CN)

(73) Assignees: CHENGDU BOE OPTOELECTRONICS TECHNOLOGY CO., LTD., CHENGDU, SICHUAN (CN); BOE TECHNOLOGY GROUP CO., LTD., BEIJING (CN); BEIJING BOE TECHNOLOGY DEVELOPMENT CO., LTD., BEIJING (CN)

(21) Appl. No.: 18/995,595

(22) PCT Filed: Oct. 31, 2023
(86) PCT No.: PCT/CN2023/128450

§ 371 Date: Jan. 16, 2025

(51) Int. Cl. G09G 3/3266

(52) U.S. Cl. CPC G09G 3/3266; G09G 2300/026; G09G 2300/0426; G09G 2330/02

(57) ABSTRACT

A display panel and a display device. In the display panel, a plurality of the edge pixel driving circuits of a plurality of edge sub-pixels in the edge pixel group are arranged in a first direction, the plurality of gate driving units and the plurality of light emitting control units are arranged in a second direction, and the second direction intersects with the first direction, the display panel further includes a clock signal line, a start line, a first power line and a second power line that are configured to drive the row driving circuit, and the plurality of gate driving units and the plurality of light emitting control units share at least one selected from a group consisting of the clock signal line, the start line, the first power line and the second power line.

### TECHNICAL FIELD

Embodiments of the present disclosure relate to a display panel and a display device.

### BACKGROUND

With the continuous development of information technology, there is a growing demand for large-sized, high-resolution screens in a wide range of scenarios, from large-scale settings such as command centers, monitoring centers, and network management centers, to smaller-scale settings like conferences and lectures. However, a single screen is insufficient to meet these requirements.

Screen splicing technology is a technology of stitching multiple screens together as a display screen, which divides a complete image into multiple sub-images and displays them on multiple screens respectively. Therefore, screen splicing technology can enable large-size and high-resolution displays. On the other hand, the screens used in screen splicing technology can not only be combined to form large-size screens, but also be displayed separately, so it has broad market prospects.

On the other hand, active matrix organic light emitting diode (AMOLED) display technology has gradually become the choice of various electronic products because of its advantages of high contrast, wide viewing angle, fast response speed and lightness. By combining AMOLED display device technology with screen splicing technology, a large-size, high-resolution, high-contrast, wide viewing angle, fast response and light display device can be realized.

### SUMMARY

The embodiments of the disclosure provide a display panel and a display device. By arranging the row driving circuit at least partially in the edge display area and overlapping with the anode of at least one edge sub-pixel in the edge pixel group, the display panel can arrange the row driving circuit at least partially under the display area without placing all the row driving circuits in the peripheral area, thereby reducing the width of the peripheral area; Moreover, by arranging a plurality of gate driving units and a plurality of light emitting control units in the second direction and making the gate driving units and the light emitting control units share at least one of the clock signal line, the start line, the first power line and the second power line, the display device can further reduce the width occupied by the row driving circuit and various driving lines, thereby further reducing the width of the peripheral area. Thus, that display panel has an extremely narrow frame.

At least one embodiment of the present disclosure provides a display device, which includes a plurality of display panels mutually spliced, wherein each of a plurality of display panels comprises: a base substrate, comprising a display area and a peripheral area; an edge pixel group, comprising a plurality of edge sub-pixels; and a row driving circuit, comprising a plurality of gate driving units and a plurality of light emitting control units, the display area comprises a middle display area and an edge display area located at a side of the middle display area close to the peripheral area, and each of a plurality of edge sub-pixels comprises an edge pixel driving circuit and an anode connected with the edge pixel driving circuit; the edge pixel group is located in the edge display area, and the row driving circuit is at least partially located in the edge display area and overlaps with the anode of at least one edge among a plurality of edge sub-pixels in the edge pixel group, a plurality of the edge pixel driving circuits of a plurality of edge sub-pixels in the edge pixel group are arranged in a first direction, the plurality of gate driving units and the plurality of light emitting control units are arranged in a second direction, and the second direction intersects with the first direction, the display panel further includes a clock signal line, a start line, a first power line and a second power line that are configured to drive the row driving circuit, and the plurality of gate driving units and the plurality of light emitting control units share at least one selected from a group consisting of the clock signal line, the start line, the first power line and the second power line.

For example, in the display device provided by an embodiment of the present disclosure, each gate driving unit of the plurality of gate driving units comprises an output transistor and an input transistor, each light emitting control unit of the plurality of light emitting control units comprises an output transistor and an input transistor, the second power line extends in the second direction and passes through the plurality of gate driving units and the plurality of light emitting control units, and the plurality of gate driving units and the plurality of light emitting control units share the second power line, the output transistor of the each gate driving unit and the output transistor of the each light emitting control unit are at a first side of the second power line in the first direction, and the input transistor of the each gate driving unit and the input transistor of the each light emitting control unit are at a second side of the second power line in the first direction.

For example, in the display device provided by an embodiment of the present disclosure, the clock signal line, the start line and the first power line are at a side of both the input transistor of the each gate driving unit and the input transistor of the each light emitting control unit away from the second power line.

For example, in the display device provided by an embodiment of the present disclosure, the second power line is located in the edge display area, and overlaps with the anode of at least one edge sub-pixel of a plurality of edge sub-pixels in the edge pixel group.

For example, in the display device provided by an embodiment of the present disclosure, the clock signal line, the start line and the first power line are located in the edge display area, and overlap with the anode of at least one edge sub-pixel of a plurality of edge sub-pixels in the edge pixel group.

For example, in the display device provided by an embodiment of the present disclosure, output terminals of two gate driving units adjacent in the second direction of the plurality of gate driving units are connected, to provide gate driving signals for the edge sub-pixels in a same row in a same edge pixel group.

For example, in the display device provided by an embodiment of the present disclosure, two of the gate driving units are arranged between two adjacent light emitting control units among the plurality of light emitting control units.

For example, in the display device provided by an embodiment of the present disclosure, the row driving circuit further comprises a dummy driving unit which is not connected with all the clock signal line, the start line and the first power line, the dummy driving unit, the plurality of gate driving units and the plurality of light emitting control units are arranged in the second direction.

For example, in the display device provided by an embodiment of the present disclosure, the dummy driving unit is inserted between the light emitting control unit corresponding to one row of the edge sub-pixels and the gate driving unit corresponding to the next row of the edge sub-pixels.

For example, in the display device provided by an embodiment of the present disclosure, the peripheral area, the edge display area and the middle display area are arranged in a first direction; in the edge pixel group, a size of the plurality of edge pixel driving circuits of the plurality of edge sub-pixels in the first direction is smaller than a size of a plurality of the anodes of the plurality of edge sub-pixels in the first direction.

For example, in the display device provided by an embodiment of the present disclosure, all the row driving circuit is located in the edge display area, and an orthographic projection of an edge of the row driving circuit away from the middle display area on the base substrate overlaps with an orthographic projection of the anode of an outermost edge sub-pixel among a plurality of edge sub-pixels in the edge pixel group on the base substrate.

For example, the display device provided by an embodiment of the present disclosure further includes: a middle pixel group, comprising a plurality of middle sub-pixels, the middle pixel group is located in the middle display area, and each middle sub-pixel among a plurality of middle sub-pixels comprises a middle pixel driving circuit and an anode connected with the middle pixel driving circuit; an area occupied by a plurality of the middle pixel driving circuits and intervals between the plurality of the middle pixel driving circuits of a plurality of middle sub-pixels in the middle pixel group is larger than an area occupied by a plurality of edge pixel driving circuits and intervals between the plurality of the edge pixel driving circuits of a plurality of edge sub-pixels in the edge pixel group.

For example, in the display device provided by an embodiment of the present disclosure, an area occupied by the intervals between a plurality of middle pixel driving circuits of a plurality of middle sub-pixels in the middle pixel group is larger than an area occupied by the intervals between a plurality of edge pixel driving circuits of a plurality of edge sub-pixels in the edge pixel group.

For example, in the display device provided by an embodiment of the present disclosure, the edge pixel group comprises a first edge sub-pixel, a second edge sub-pixel and a third edge sub-pixel, and the middle pixel group comprises a first middle sub-pixel, a second middle sub-pixel and a third middle sub-pixel; the first edge sub-pixel and the first middle sub-pixel are configured to emit light of a first color, the second edge sub-pixel and the second middle sub-pixel are configured to emit light of a second color, and the third edge sub-pixel and the third middle sub-pixel are configured to emit light of a third color.

For example, in the display device provided by an embodiment of the present disclosure, a size of the anode of the first edge sub-pixel is the same as a size of the anode of the first middle sub-pixel, a size of the anode of the second edge sub-pixel is the same as a size of the anode of the second middle sub-pixel, and a size of the anode of the third edge sub-pixel is the same as a size of the anode of the third middle sub-pixel.

For example, in the display device provided by an embodiment of the present disclosure, the row driving circuit is located at a side of a plurality of edge pixel driving circuits in the edge pixel group away from the middle display area.

For example, in the display device provided by an embodiment of the present disclosure, each edge sub-pixel further comprises: an edge organic light emitting layer, located at a side of the anode away from the base substrate; and a cathode, located at a side of the edge organic light emitting layer away from the base substrate.

At least one embodiment of the present disclosure further provides a display panel, which includes: a base substrate, comprising a display area and a peripheral area; an edge pixel group, comprising a plurality of edge sub-pixels; and a row driving circuit, comprising a plurality of gate driving units and a plurality of light emitting control units, the display area comprises a middle display area and an edge display area located at a side of the middle display area close to the peripheral area, and each of a plurality of edge sub-pixels comprises an edge pixel driving circuit and an anode connected with the edge pixel driving circuit; the edge pixel group is in the edge display area, and the row driving circuit is at least partially located in the edge display area and overlaps with the anode of at least one edge sub-pixel in the edge pixel group, a plurality of the edge pixel driving circuits of a plurality of edge sub-pixels in the edge pixel group are arranged in a first direction, the plurality of gate driving units and the plurality of light emitting control units are arranged in a second direction, and the second direction is perpendicular to the first direction, the display panel further includes a clock signal line, a start line, a first power line and a second power line that are configured to drive the row driving circuit, and the plurality of gate driving units and the plurality of light emitting control units share at least one selected from a group consisting of the clock signal line, the start line, the first power line and the second power line.

For example, in the display panel provided by an embodiment of the present disclosure, each gate driving unit of the plurality of gate driving units comprises an output transistor and an input transistor, each light emitting control unit of the plurality of light emitting control units comprises an output transistor and an input transistor, the second power line extends in the second direction and passes through the plurality of gate driving units and the plurality of light emitting control units, and the plurality of gate driving units and the plurality of light emitting control units share the second power line, the output transistor of the each gate driving unit and the output transistor of the each light emitting control unit are at a first side of the second power line in the first direction, and the input transistor of the each gate driving unit and the input transistor of the each light emitting control unit are at a second side of the second power line in the first direction.

For example, in the display panel provided by an embodiment of the present disclosure, the clock signal line, the start line and the first power line are at a side of both the input transistor of the each gate driving unit and the input transistor of the each light emitting control unit away from the second power line.

For example, in the display panel provided by an embodiment of the present disclosure, the second power line is located in the edge display area, and overlaps with the anode of at least one edge sub-pixel of a plurality of edge sub-pixels in the edge pixel group.

For example, in the display panel provided by an embodiment of the present disclosure, the clock signal line, the start line and the first power line are located in the edge display area, and overlap with the anode of at least one edge sub-pixel of a plurality of edge sub-pixels in the edge pixel group.

### BRIEF DESCRIPTION OF DRAWINGS

In order to explain the technical solution of the embodiments of the application more clearly, the drawings of the embodiments will be briefly introduced below. Obviously, the drawings in the following description only relate to some embodiments of the application, and are not limitations of the application.

FIG. 1 is a schematic diagram of a display panel provided by an embodiment of the present disclosure;

FIG. 2 is a partial schematic diagram of a row driving circuit provided by an embodiment of the present disclosure;

FIG. 3 is an overlapping schematic diagram of a row driving circuit and an anode in a display panel provided by an embodiment of the present disclosure;

FIG. 4 is an equivalent circuit diagram of a gate driving unit in a display panel provided by an embodiment of the present disclosure;

FIG. 5A-FIG. 5E are layout diagrams of a gate driving unit in a display panel provided by an embodiment of the disclosure;

FIG. 6 is an equivalent circuit diagram of a light emitting control unit in a display panel provided by an embodiment of the present disclosure;

FIG. 7A-FIG. 7E are layout diagrams of a light emitting control unit in a display panel provided by an embodiment of the present disclosure;

FIG. 8 is a schematic sectional view of an edge sub-pixel in a display panel provided by an embodiment of the present disclosure;

FIG. 9 is a schematic diagram of another display panel provided by an embodiment of the present disclosure;

FIG. 10 is a schematic diagram of a row driving circuit in a display panel provided by an embodiment of the present disclosure;

FIG. 11 is a schematic diagram of signal line connection of a row driving circuit in a display panel provided by an embodiment of the present disclosure;

FIG. 12 is a schematic diagram of another display panel provided by an embodiment of the present disclosure; and

FIG. 13 is a schematic diagram of a display device provided by an embodiment of the present disclosure.

### DETAILED DESCRIPTION

In order to make the purpose, technical scheme and advantages of the embodiment of the application more clear, the technical scheme of the embodiment of the application will be described clearly and completely with the attached drawings. Obviously, the described embodiment is a part of the embodiment of this application, not the whole embodiment. Based on the described embodiments of the application, all other embodiments obtained by ordinary people in the field without creative labor belong to the protection scope of the application.

Unless otherwise defined, technical terms or scientific terms used in this application shall have their ordinary meanings as understood by people with ordinary skills in the field to which this application belongs. The words “first”, “second” and similar words used in this application do not indicate any order, quantity or importance, but are only used to distinguish different components. Similar words such as “including” or “containing” mean that the elements or objects appearing before the word cover the elements or objects listed after the word and their equivalents, without excluding other elements or objects. Similar words such as “connected” or “connected” are not limited to physical or mechanical connection, but may include electrical connection, whether direct or indirect.

In the screen splicing technology, in order to achieve excellent display effect, achromatic splicing and seamless splicing are very important technical points, and in order to achieve seamless splicing, the screens used for splicing need to have extremely narrow extremely narrow frames.

In this regard, the embodiments of the present disclosure provide a display panel and a display device. The display panel includes a base substrate, an edge pixel group, and a row driving circuit. The base substrate includes a display area and a peripheral area; the edge pixel group includes a plurality of edge sub-pixels; and the row driving circuit includes a plurality of gate driving units and a plurality of light emitting control units; the display area includes a middle display area and an edge display area located at a side of the middle display area close to the peripheral area, and each of a plurality of edge sub-pixels includes an edge pixel driving circuit and an anode connected with the edge pixel driving circuit; the edge pixel group is located in the edge display area, and the row driving circuit is at least partially located in the edge display area and overlaps with the anode of at least one edge among a plurality of edge sub-pixels in the edge pixel group, a plurality of the edge pixel driving circuits of a plurality of edge sub-pixels in the edge pixel group are arranged in a first direction, the plurality of gate driving units and the plurality of light emitting control units are arranged in a second direction, and the second direction intersects with the first direction, the display panel further includes a clock signal line, a start line, a first power line and a second power line that are configured to drive the row driving circuit, and the plurality of gate driving units and the plurality of light emitting control units share at least one selected from a group consisting of the clock signal line, the start line, the first power line and the second power line. Therefore, by arranging the row driving circuit at least partially in the edge display area and overlapping with the anode of at least one edge sub-pixel in the edge pixel group, the display panel can arrange the row driving circuit at least partially under the display area without placing all the row driving circuits in the peripheral area, thereby reducing the width of the peripheral area; moreover, by arranging the plurality of gate driving units and the plurality of light emitting control units in the second direction and making the gate driving units and the light emitting control units share at least one selected from the group consisting of the clock signal line, the start line, the first power line and the second power line, the display device can further reduce the width occupied by the row driving circuit and the various driving lines, thereby further reducing the width of the peripheral area. Thus, the display panel has an extremely narrow frame.

The embodiments of the present disclosure also provide a display device, which includes a plurality of the display panels mentioned above spliced with each other. The display device can combine a plurality of display panels into a large-size and high-resolution display device by splicing. Moreover, because the display panel has an extremely narrow frame, the display device can realize seamless splicing, thereby providing excellent display effect.

Next, the display panel and the display device provided by the embodiments of the present disclosure will be described in detail with the attached drawings.

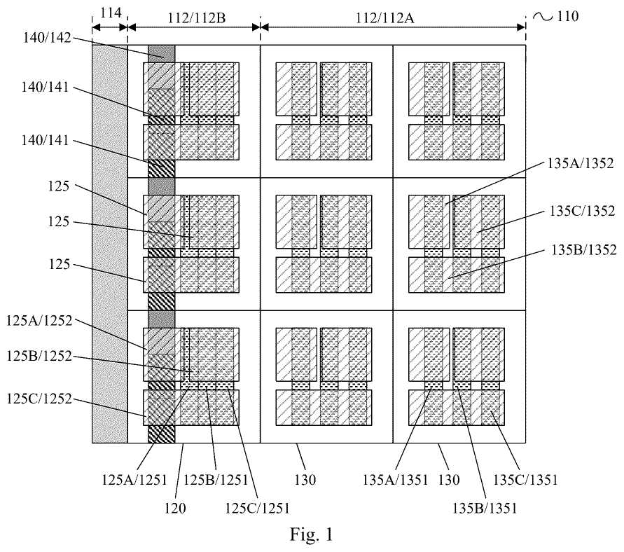

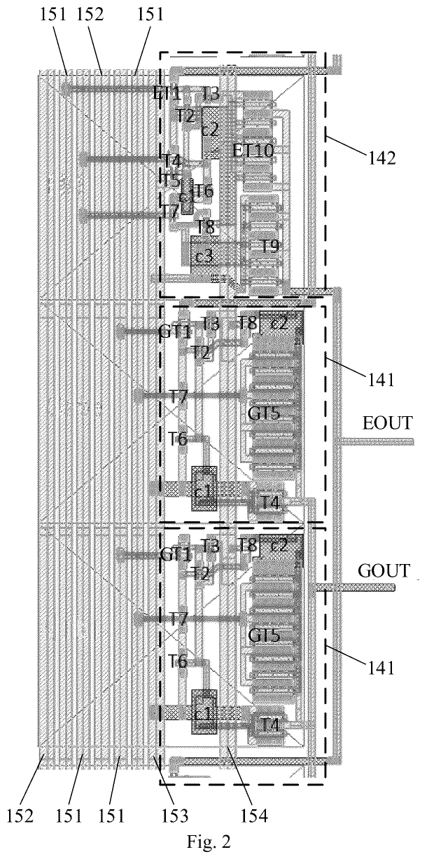

FIG. 1 is a schematic diagram of a display panel provided by an embodiment of the present disclosure; FIG. 2 is a partial schematic diagram of a row driving circuit provided by an embodiment of the present disclosure. As illustrated by FIG. 1, the display panel 100 includes a substrate 110, an edge pixel group 120 and a row driving circuit 140. The base substrate 110 includes a display area 112 and a peripheral area 114; the edge pixel group 120 includes a plurality of edge sub-pixels 125; the row driving circuit 140 includes a plurality of gate driving units 141 and a plurality of light emitting control units 142; the display area 112 includes a middle display area 112A and an edge display area 112B located in the middle display area 112A close to the peripheral area 114. Each edge sub-pixel 125 includes an edge pixel driving circuit 1251 and an anode 1252 connected to the edge pixel driving circuit 1251, and the edge pixel driving circuit 1251 can provide a driving current to the anode 1252 to drive the light emitting layer on the anode 1252 for luminescent display.

As illustrated by FIG. 1, the edge pixel group 120 is located in the edge display area 112B, and the row driving circuit 140 is at least partially located in the edge display area 112B and overlaps with the anode 1252 of at least one edge sub-pixel 125 in the edge pixel group 120. That is, the orthographic projection of the row driving circuit 140 on the base substrate 110 overlaps with the orthographic projection of the anode 1252 of at least one edge sub-pixel 124 in the edge pixel group 120 on the base substrate 110.

In a common display panel, the Gate Driver on Array (GOA) technology can be used to integrate the row driving circuit in the peripheral area, so that the row driving circuit can directly provide row driving signals such as gate driving signals and light emitting control signals for the sub-pixel array without additional gate driving chips and corresponding binding structures, thus reducing the cost and the frame width. However, in this case, the row driving circuit itself will still occupy a certain width, and it is impossible to achieve an extremely narrow frame.

In the display panel provided by the embodiments of the present disclosure, by arranging the row driving circuit at least partially in the edge display area and overlapping with the anode of at least one edge sub-pixel in the edge pixel group, the display panel can arrange the row driving circuit at least partially under the display area without placing all the row driving circuits in the peripheral area, thereby reducing the width of the peripheral area.

Further, as illustrated by FIG. 1, a plurality of edge pixel driving circuits 1251 of a plurality of edge sub-pixels 125 in the edge pixel group 120 are arranged in a first direction, and the plurality of gate driving units 141 and the plurality of light emitting control units 142 are arranged in in a second direction, which the second direction intersects with the first direction. As illustrated by FIG. 2, the display panel 100 further includes a clock signal line 151, a start line 152, a first power line 153 and a second power line 154, which are configured to drive the row driving circuit 140; the plurality of gate driving units 141 and the plurality of light emitting control units 142 share at least one selected from a group consisting of the clock signal line 151, the start line 152, the first power line 153 and the second power line 154.

In a common display panel, the row driving circuit needs to provide the gate driving signal and the emission driving signal to the pixel driving circuit in the display area, and the gate driving unit providing the gate driving signal and the light emitting control unit providing the light emitting control signal are arranged side by side, that is, arranged in the first direction, so the size in the first direction is larger. In the display panel provided by the embodiments of the present disclosure, by arranging the plurality of gate driving units and the plurality of light emitting control units in the second direction, the size of the row driving circuits in the display panel can be reduced in the first direction, so that all the row driving circuits can be arranged in the edge display area. Moreover, by sharing at least one selected from a group consisting of the clock signal line, the start line, the first power line and the second power line with the plurality of gate driving units and the plurality of light emitting control units, the width occupied by the row driving circuit and various driving lines of the display device can be further reduced, thereby the width of the peripheral area further reduced. Through the above various designs, the display panel has an extremely narrow frame. Furthermore, when the display panel provided by the embodiments of the present disclosure is used for splicing display, the spliced display device can realize seamless splicing and has excellent display effect.

For example, the first direction and the second direction may be perpendicular to each other. Of course, the embodiments of the present disclosure include but are not limited to this.

In some examples, as illustrated by FIG. 2, the plurality of gate driving units 141 and the plurality of light emitting control units 142 share the clock signal line 151, the start line 152, the first power line 153 and the second power line 154, thereby minimizing the number of signal lines.

In some examples, as illustrated by FIG. 2, each gate driving unit 141 includes an output transistor GT5 and an input transistor GT1, and the light emitting control unit 142 includes an output transistor ET10 and an input transistor ET1. The second power line 154 extends along the second direction and passes through the plurality of gate driving units 141 and the plurality of light emitting control units 142, and the plurality of gate driving units 141 and the plurality of light emitting control units 142 share the second power line 154. The output transistor GT5 of the gate driving unit 141 and the output transistor ET10 of the light emitting control unit 142 are located at the first side of the second power line 154 in the first direction, and the input transistor GT1 of the gate driving unit 142 and the input transistor ET1 of the light emitting control unit 142 are located at the second side of the second power line 154 in the first direction. That is, the output transistor GT5 of the gate driving unit 141 and the output transistor ET10 of the light emitting control unit 142 are located on the same side of the second power line 154 in the first direction, and the input transistor GT1 of the gate driving unit 142 and the input transistor ET1 of the light emitting control unit 142 are located on the other side of the second power line 154 in the first direction. Therefore, the display panel can use the space occupied by the gate driving unit and the light-emitting control unit to set the second power line, so that on one hand, the layout of the second power line, the gate driving unit and the light-emitting control unit is more compact and the wiring is easier, and on the other hand, the width occupied by the row driving circuit and the second power line as a whole can be further reduced.

It should be noted that although FIG. 2 shows the specific circuit structures adopted by the gate driving unit and the light emitting control unit, the specific circuit structures of the gate driving unit and the light emitting control unit provided by the embodiments of this disclosure include but are not limited to this; on the other hand, because the output transistor usually needs to have a large area (caused by a large channel width-length ratio), even if the gate driving unit and the light emitting control unit adopt other types of specific circuit structures, the above design can still be adopted. In addition, In addition, in order to show the position of each transistor and capacitor more clearly, the letter “G” is omitted from the reference numerals of other transistors and capacitors in the gate driving unit 141 in FIG. 2, and the letter “E” is omitted from the reference numerals of other transistors and capacitors in the light emission control unit 142.

In some examples, as illustrated by FIG. 2, the clock signal line 151, the start line 152, and the first power line 153 are located on the side where the input transistor GT1 of the gate driving unit 141 and the input transistor ET1 of the light emitting control unit 142 are away from the second power line 154.

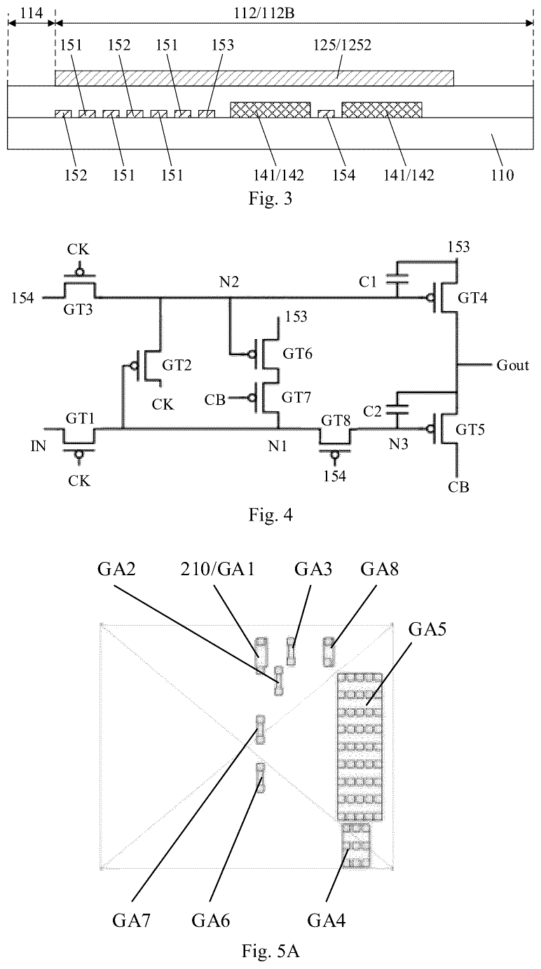

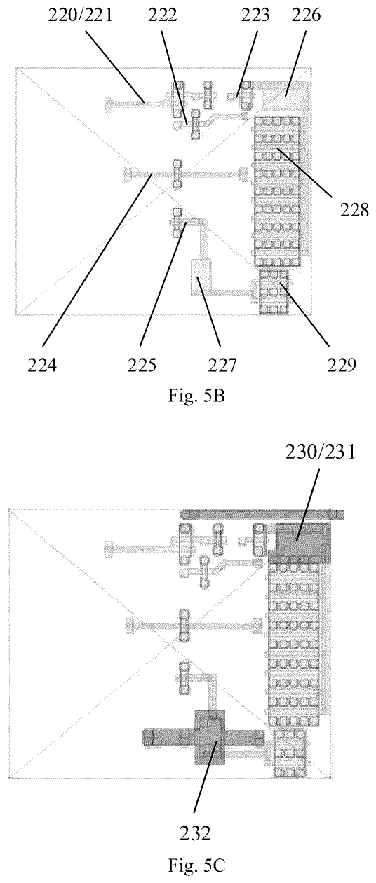

FIG. 3 is an overlapping schematic diagram of a row driving circuit and an anode in a display panel provided by an embodiment of the present disclosure. As illustrated by FIG. 3, the second power line 154 is located in the edge display area 112B and overlaps with the anode 1252 of at least one edge sub-pixel 125 in the edge pixel group 120.

In some examples, as illustrated by FIG. 3, the clock signal line 151, the start line 152 and the first power line 153 are located in the edge display area 112B and overlap with the anode 1252 of at least one edge sub-pixel 125 in the edge pixel group 120. Therefore, the width of the peripheral area in the display panel can be further reduced.

In some examples, as illustrated by FIG. 2, the output terminals of two adjacent gate driving units 141 in the second direction are connected, so as to provide gate driving signals for the edge sub-pixels 125 located in the same row in the same edge pixel group 120, thus reducing the fluctuation of the gate driving signals and stabilizing the input of data voltage.

In some examples, as illustrated by FIG. 1 and FIG. 2, two gate driving units 141 are arranged between two adjacent light emitting control units 142. The two gate driving units 141 jointly provide gate driving signals for sub-pixels (including edge sub-pixels and middle sub-pixels) located in the same row, so that the fluctuation of gate driving signals can be reduced and the input of data voltage can be stabilized.

In some examples, as illustrated by FIG. 1, the peripheral area 114, the edge display area 112B and the middle display area 112A are arranged in the first direction; In the edge pixel group 120, the dimensions of a plurality of the edge pixel driving circuits 1251 of a plurality of the edge sub-pixels 125 in the first direction are smaller than the dimensions of a plurality of the anodes 1252 of a plurality of the edge sub-pixels 125 in the first direction. By reducing the space occupied by the edge pixel driving circuit 1251 of the display panel, the row driving circuit 140 can overlap with the anode 1252 of at least one edge sub-pixel 125 in the edge pixel group 120, thereby reducing the frame width of the display panel.

In some examples, as illustrated by FIG. 1, the row driving circuits 140 are all located in the edge display area 112A, and the orthographic projection of the edge of the row driving circuits 140 away from the middle display area 112a on the substrate substrate 110 overlaps with the orthographic projection of the anode 1252 of the outermost edge sub-pixel 125 in the edge pixel group 120 on the substrate substrate 110. Therefore, the width of the peripheral area of the display panel can be reduced to the maximum extent.

In some examples, as illustrated by FIG. 1, the display panel 100 further includes a middle pixel group 130 including a plurality of middle sub-pixels 135; the middle pixel group 130 is located in the middle display area 112A, and each middle sub-pixel 135 includes a middle pixel driving circuit 1351 and an anode 1352 connected to the middle pixel driving circuit 1351. An area occupied by a plurality of middle pixel driving circuits 1351 and a plurality of middle pixel driving circuits 1351 of a plurality of middle sub-pixels 135 in the middle pixel group 130 is larger than an area occupied by a plurality of edge pixel driving circuits 1251 and a plurality of edge pixel driving circuits 1251 of a plurality of edge sub-pixels 125 in the edge pixel group 120. Thus, by reducing the interval area between the edge pixel driving circuit and the edge pixel driving circuit of the display panel, the row driving circuit 140 can overlap with the anode 1252 of at least one edge sub-pixel 125 in the edge pixel group 120, thereby reducing the frame width of the display panel.

It should be noted that the middle sub-pixel and the edge sub-pixel here are only different in position and some structures, and they are all sub-pixels used to display the same image; in some examples, the kind, color and size of light emitted by the middle sub-pixel and the edge sub-pixel are the same.

In some examples, as illustrated by FIG. 1, the area occupied by the intervals between a plurality of the middle pixel driving circuits 1351 of a plurality of the middle sub-pixels 135 in the middle pixel group 130 is larger than the area occupied by the intervals between a plurality of the edge pixel driving circuits 1251 of a plurality of the edge sub-pixels 125 in the edge pixel group 120. Thus, by reducing the area occupied by the interval between the edge pixel driving circuits of the display panel, the row driving circuit 140 can overlap with the anode 1252 of at least one edge sub-pixel 125 in the edge pixel group 120, thereby reducing the frame width.

In some examples, as illustrated by FIG. 1, the edge pixel group 120 includes a first edge sub-pixel 125A, a second edge sub-pixel 125B and a third edge sub-pixel 125C; that is, the edge sub-pixel 125 includes the first edge sub-pixel 125A, the second edge sub-pixel 125B, and the third edge sub-pixel 125C. The middle pixel group 130 includes a first middle sub-pixel 135A, a second middle sub-pixel 135B and a third middle sub-pixel 135C; that is, the middle sub-pixel 135 includes the first middle sub-pixel 135A, the second middle sub-pixel 135B, and the third middle sub-pixel 135C. The first edge sub-pixel 125A and the first middle sub-pixel 135A are configured to emit light of a first color, the second edge sub-pixel 125B and the second middle sub-pixel 135B are configured to emit light of a second color, and the third edge sub-pixel 125C and the third middle sub-pixel 135C are configured to emit light of a third color. Therefore, the edge pixel group and the middle pixel group of the display panel have the same composition.

For example, the first color is red, the second color is green, and the third color is blue. Of course, the embodiments of the present disclosure include but are not limited to this, and the first color, the second color and the third color may also be other colors.

In some examples, as illustrated by FIG. 1, the anode of the first edge sub-pixel 125A has the same size as the anode of the first middle sub-pixel 135A, the anode of the second edge sub-pixel 125B has the same size as the anode of the second middle sub-pixel 135B, and the anode of the third edge sub-pixel 125C has the same size as the anode of the third middle sub-pixel 135C. Therefore, the display quality of the display panel can be improved.

In some examples, as illustrated by FIG. 1, the size of the anode of the third edge sub-pixel 125C is larger than that of the first edge sub-pixel 125A and that of the second edge sub-pixel 125B; the size of the anode of the third middle sub-pixel 135C is larger than that of the first middle sub-pixel 135A and that of the second middle sub-pixel 135B. Therefore, the service life of sub-pixels of the display panel for different color can be balanced.

In some examples, as illustrated by FIG. 1, the row driving circuit 140 is located on a side of a plurality of edge pixel driving circuits 1251 in the edge pixel group 120 away from the middle display area 112B. Of course, the embodiments of the present disclosure include, but are not limited to this, and the row driving circuit may also be located between a plurality of edge pixel driving circuits in the edge pixel group.

FIG. 4 is an equivalent circuit diagram of a gate driving unit in a display panel provided by an embodiment of the present disclosure. As illustrated by FIG. 4, the gate driving unit 141 includes an input transistor GT1, a first control transistor GT2, a second control transistor GT3, an output control transistor GT4, an output transistor GT5, a first noise reduction transistor GT7, a second noise reduction transistor GT6, a voltage stabilizing transistor GT8, a first capacitor GC1 and a second capacitor GC2. The gate of the input transistor GT1 is connected with the first clock signal terminal CK (the first clock signal terminal CK is connected with the first clock signal line GCK) to receive the first clock signal, the second electrode of the input transistor GT1 is connected with the input terminal IN, and the first electrode of the input transistor GT1 is connected with the first node N1. For example, when the gate driving unit 141 is a first-stage gate driving unit, the input terminal IN is connected with the start line 152 to receive the start signal, and when the gate driving unit 141 is other gate driving units except the first-stage gate driving unit, the input terminal IN is connected with the output terminal GOUT of its superior gate driving unit.

The gate of the first control transistor GT2 is connected with the first node N1, the second electrode of the first control transistor GT2 is connected with the first clock signal terminal CK (the first clock signal terminal CK is connected with the first clock signal line GCK) to receive the first clock signal, and the first electrode of the first control transistor GT2 is connected with the second node N2.

The gate of the second control transistor GT3 is connected with the first clock signal terminal CK (the first clock signal terminal CK is connected with the first clock signal line GCK) to receive the first clock signal, the second electrode of the second control transistor GT3 is connected with the second power line 154 to receive the low-level signal, and the first electrode of the second control transistor GT3 is connected with the second node N2.

The gate of the output control transistor GT4 is connected with the second node N2, the first electrode of the output control transistor GT4 is connected with the first power line 153 to receive the high-level signal, and the second electrode of the output control transistor GT4 is connected with the output terminal GOUT.

The first electrode of the first capacitor GC1 is connected with the second node N2, and the second electrode of the first capacitor GC1 is connected with the first power line 153.

The gate of the output transistor GT5 is connected with the third node N3, the first electrode of the output transistor GT5 is connected with the second clock signal terminal CB (the second clock signal terminal CB is connected with the second clock signal line GCB), and the second electrode of the output transistor GT5 is connected with the output terminal GOUT.

The first electrode of the second capacitor GC2 is connected with the third node N3, and the second electrode of the second capacitor GC2 is connected with the output terminal GOUT.

The gate of the first noise reduction transistor GT7 is connected with the second clock signal terminal CB (the second clock signal terminal CB is connected with the second clock signal line GCB) to receive the second clock signal, and the first electrode of the first noise reduction transistor GT7 is connected with the first node N1.

The gate of the second noise reduction transistor GT6 is connected with the second node N2, the first electrode of the second noise reduction transistor GT6 is connected with the first power line 153 to receive the high-level signal, and the second electrode of the second noise reduction transistor GT6 is connected with the second electrode of the first noise reduction transistor GT7.

The gate of the voltage stabilizing transistor GT8 is connected with the second power line 154 to receive the low-level signal, the first electrode of the voltage stabilizing transistor GT8 is connected with the first node N1, and the second electrode of the voltage stabilizing transistor GT8 is connected with the third node N3.

The transistors in the gate driving unit 141 shown in FIG. 4 are all described by taking a P-type transistor as an example, that is, each transistor is turned on when the gate is turned on at a low level (Conduction Level), and turned off when the gate is turned on at a high level (Cut-off Level). In this case, the first electrode of the transistor can be the source, and the second electrode of the transistor can be the drain. In other embodiments, the first and second electrodes of the transistor can be interchanged. Of course, the embodiments of the present disclosure include but are not limited to this, and each transistor in the gate driving unit 141 can also adopt an N-type transistor or a mixture of a P-type transistor and an N-type transistor, as long as the port polarity of the selected transistor is simultaneously connected according to the port polarity of the corresponding transistor in the embodiments of the present disclosure.

It should be noted that the clock signal line 151 includes the first clock signal line GCK and the second clock signal line GCB described above. The transistors used in the gate driving unit can all be thin film transistors or field effect transistors or other switching devices with the same characteristics. Here, all thin film transistors are taken as examples to explain. For example, the active layer (channel area) of the transistor is made of semiconductor materials, such as polysilicon (e.g, low-temperature polysilicon or high-temperature polysilicon), amorphous silicon, indium gallium zinc oxide (IGZO), and the gate, source and drain are made of metal materials, such as aluminum or aluminum alloy. The source and drain of the transistor used here can be symmetrical in structure, so there can be no difference in structure between the source and drain. In the embodiments of the present disclosure, in order to distinguish the two electrodes of the transistor except the gate, one of them is directly described as the first electrode and the other as the second pole. Furthermore, in the embodiments of the present disclosure, the electrodes of the capacitor may be metal electrodes or one of the electrodes may be made of semiconductor materials (e.g., doped polysilicon).

Next, an example of a working process of the gate driving unit will be introduced. The working process of the gate driving unit 141 includes four stages, namely, the first stage t1, the second stage t2, the third stage t3 and the fourth stage t4.

In the input stage t1, the first clock signal provided on the first clock signal terminal CK is the low-level signal, and the second clock signal provided on the second clock signal terminal CB is the high-level signal. The input terminal IN receives the start signal on the start line 152 or the start signal provided by the output terminal of the previous gate driving unit. For example, the start signal is equal to the low-level signal VL provided by the second power line 154. Since the first clock signal is the low-level signal, the input transistor GT1 is turned on, and the input signal Vin of the input terminal IN is transmitted to the first node N1 via the input transistor GT1. Since the low-level signal transmitted by the input transistor GT1 has a threshold loss, the voltage of the first node N1 is Vin-Vth1, that is, VL-Vth1, wherein Vth1 represents the threshold voltage of the input transistor GT1. Since the gate of the voltage stabilizing transistor GT8 receives the low-level signal provided by the second power line 154, the voltage stabilizing transistor GT8 is in a turn-on state, and thus the voltage VL-Vth1 is transmitted to the third node N3 via the voltage stabilizing transistor GT8. For example, the threshold voltage of the voltage stabilizing transistor GT8 is expressed as Vth8. Similarly, because the voltage stabilizing transistor GT8 transmits the low-level signal with threshold loss, the voltage of the third node N3 is VL-VthN1, wherein VthN1 is the smaller of Vth1 and Vth8. The voltage of the third node N3 can control the turn-on of the output transistor GT5, and the second clock signal is written into the output terminal GOUT via the output transistor GT5 as an output signal (i.e., a gate driving signal), that is, in the input stage t1, the output signal is the high-level second clock signal, i.e., the high-level signal VH provided by the first power line 153.

In the input stage t1, because the first clock signal is the low-level signal, the second control transistor GT3 is turned on, and the low-level signal provided by the second power line 154 is transmitted to the second node N2 via the second control transistor GT3. Because the voltage of the first node N1 is VL-Vth1, the first control transistor GT2 is turned on, and the low-level first clock signal is transmitted to the second node N2 via the first control transistor GT2. For example, the threshold voltage of the first control transistor GT2 is expressed as Vth2, the threshold voltage of the second control transistor GT3 is expressed as Vth3, and when vth3<vth2+vth1, the voltage of the second node N2 is VL-Vth3. In this case, both the output control transistor GT4 and the second noise reduction transistor GT6 are turned on. Since the second clock signal is the high level signal, the first noise reduction transistor GT7 is turned off.

In the output stage t2, the first clock signal provided on the first clock signal terminal CK is the high-level signal, the second clock signal provided on the second clock signal terminal CB is the low-level signal, and the start signal of the input terminal IN received on the start line 152 or the input signal Vin of the input terminal IN provided by the output terminal of the previous gate driving unit is the high-level signal. The output transistor GT5 is turned on, and the second clock signal is written into the output terminal GOUT as an output signal via the output transistor GT5. In the input stage t1, the voltage of the end of the second capacitor GC2 connected to the output terminal GOUT is the high-level signal VH provided by the first power line 153, and the voltage of the end of the second capacitor GC2 connected to the third node N3 is VL-VthN1, while in the output stage t2, the voltage of the end of the second capacitor GC2 connected to the output terminal GOUT becomes the low-level signal provided by the second power line 154. Due to the bootstrap function of the second capacitor GC2, the voltage at the end of the second capacitor GC2 connected to the third node N3 becomes 2VL-VthN1-VH, that is, the voltage at the third node N3 becomes 2VL-VthN1-VH. In this case, the voltage stabilizing transistor GT8 is turned off, and the output transistor GT5 can be turned on better, and the output signal is the low-level signal provided by the second power line 154.

In the output stage t2, the first clock signal is the high level signal, so that both the input transistor GT1 and the second control transistor GT3 are turned off. The voltage of the first node N1 is still VL-VthN1, the first control transistor GT2 is turned on, and the high-level first clock signal is transmitted to the second node N2 via the first control transistor GT2, that is, the voltage of the second node N2 is the high-level signal VH, so that both the output control transistor GT4 and the second noise reduction transistor GT6 are turned off. Since the second clock signal is the low-level signal, the first noise reduction transistor GT7 is turned on.

In the buffer stage t3, the first clock signal provided on the first clock signal terminal CK and the second clock signal provided on the second clock signal terminal CB are both high-level signals, and the start signal of the start line 152 received on the input terminal IN or the input signal Vin on the input terminal IN provided aon the output terminal of the previous gate driving unit is the high-level signal. The output transistor GT5 is turned on, and the second clock signal is written into the output terminal GOUT as an output signal via the output transistor GT5. In this case, the output signal is the high-level second clock signal, that is, the high-level signal VH. Due to the bootstrap function of the second capacitor GC2, the voltage of the third node N3 becomes VL-VthN1.

In the buffer stage t3, the first clock signal is the high level signal, so that both the input transistor GT1 and the second control transistor GT3 are turned off. The voltage of the third node N3 becomes VL-VthN1. In this case, the voltage stabilizing transistor GT8 is turned on, the voltage of the first node N1 is also VL-VthN1, the first control transistor GT2 is turned on, and the high-level first clock signal is transmitted to the second node N2 via the first control transistor GT2, that is, the voltage of the second node N2 is the high-level signal VH, so that both the second noise reduction transistor GT6 and the output control transistor GT4 are turned off. Since the second clock signal is the high level signal, the first noise reduction transistor GT7 is turned off.

In the first sub-phase t41 of the stabilization phase t4, the first clock signal provided on the first clock signal terminal CK is the low-level signal, the second clock signal provided on the second clock signal terminal CB is the high-level signal, and the input terminal IN receives the input signal Vin of the input terminal IN provided by the output terminal of the previous gate driving unit as the high-level signal, for example, the input signal vin of the input terminal IN is equal to the high-level signal VH provided by the first power line 153. Since the first clock signal is the low-level signal, the input transistor GT1 is turned on, and the input signal Vin of the input terminal IN is transmitted to the first node N1 via the input transistor GT1. Since the input transistor GT1 transmits the high-level signal without threshold loss, the voltage of the first node N1 is the input signal Vin of the input terminal IN (i.e., the high-level signal VH), and the first control transistor GT2 is turned off. Since the voltage stabilizing transistor GT8 is in the turn-on state, the voltage of the third node N3 is the same as that of the first node N1, that is, the voltage of the third node N3 is VH, and the output transistor GT5 is turned off. Because the first clock signal is the low-level signal, the second control transistor GT3 is turned on, the voltage of the second node N2 is VL-Vth1, the second noise reduction transistor GT6 and the output control transistor GT4 are both turned on, and the high-level signal VH is transmitted to the output terminal GOUT via the output control transistor GT4, that is, the output signal is the high-level signal VH.

In the second sub-stage t42 of the stabilization stage t4, the first clock signal provided on the first clock signal terminal CK is the high-level signal, the second clock signal provided on the second clock signal terminal CB is the low-level signal, and the input terminal IN receives the input signal Vin of the input terminal IN provided by the output terminal of the previous gate driving unit as the high-level signal. The voltages of the first node N1 and the third node N3 are the input signal Vin of the input terminal IN (i.e., the high-level signal VH provided by the first power line 153), and both the first control transistor GT2 and the output transistor GT5 are turned off. The first clock signal is the high-level signal, so that both the input transistor GT1 and the second control transistor GT3 are turned off. Due to the holding function of the first capacitor GC1, the voltage of the second node N2 is still VL-Vth3, and both the output control transistor GT4 and the second noise reduction transistor GT6 are turned on. The high-level signal VH is transmitted to the output terminal GOUT via the output control transistor GT4, and the output signal is the high-level signal VH.

In the second sub-phase t42, because the second clock signal is the low-level signal, the first noise reduction transistor GT7 is turned on, so that the high-level signal VH is transmitted to the third node N3 and the first node N1 via the second noise reduction transistor GT6 and the first noise reduction transistor GT7, so that the voltage of the first node N1 and the voltage of the third node N3 are kept at a high level.

In the third sub-stage t43 of the stabilization stage t4, the first clock signal provided on the first clock signal terminal CK and the second clock signal provided on the second clock signal terminal CB are both high-level signals, and the input terminal IN receives the input signal Vin of the input terminal IN provided by the output terminal of the previous gate driving unit as the high-level signal. The voltages of the first node N1 and the third node N3 are the high-level signals VH, and the first control transistor GT2 and the output transistor GT5 are turned off. The first clock signal is the high level signal, so that both the input transistor GT1 and the second control transistor GT3 are turned off, the voltage of the second node N2 is still VL-Vth3, and both the output control transistor GT4 and the second noise reduction transistor GT6 are turned on. The high-level signal VH is transmitted to the output terminal GOUT via the output control transistor GT4, and the output signal is the high-level signal VH.

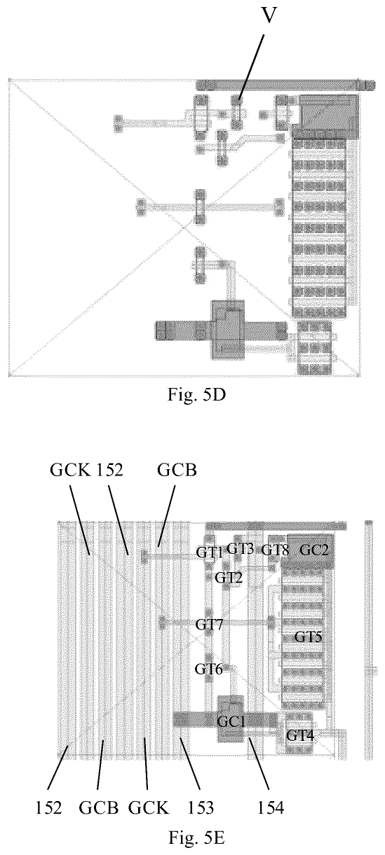

FIG. 5A-FIG. 5E are layout diagrams of a gate driving unit in a display panel provided by an embodiment of the present disclosure.

FIG. 5A shows a semiconductor layer 210, which includes an active layer GA1 of an input transistor GT1, an active layer GA2 of a first control transistor GT2, an active layer GA3 of a second control transistor GT3, an active layer GA4 of an output control transistor GT4, an active layer GA5 of an output transistor GT5, an active layer GA7 of a first noise reduction transistor GT7, an active layer GA6 of a second noise reduction transistor GT6 and an active layer GA8 of a voltage stabilizing transistor GT8. The active layer GA5 of the output transistor GT5 has a larger channel width-length ratio, so that the leakage current can be reduced.

FIG. 5B shows a gate layer 220, which includes a first connection line 221, a second connection line 222, a third connection line 223, a fourth connection line 224, a fifth connection line 225, a first electrode block 226, a second electrode block 227, a first comb electrode 228 and a second comb electrode 229.

For example, as illustrated by FIG. 5B, the first connection line 221 overlaps with the active layer of the input transistor GT1 and the active layer of the second control transistor GT3, respectively. The overlapping part of the first connection line 221 and the active layer of the input transistor GT1 can be used as the gate of the input transistor GT1, and the overlapping part of the first connection line 221 and the active layer of the second control transistor GT3 may serve as the gate of the second control transistor GT3.

For example, as illustrated by FIG. 5B, the second connection line 222 overlaps with the active layer GA2 of the first control transistor GT2, and the overlapping part of the second connection line 222 and the active layer GA2 of the first control transistor GT2 may serve as the gate of the first control transistor GT2.

For example, as illustrated by FIG. 5B, the third connection line 223 overlaps with the active layer GA8 of the voltage stabilizing transistor GT8, and the overlapping part of the third connection line 223 and the active layer GA8 of the voltage stabilizing transistor GT8 may serve as the gate of the voltage stabilizing transistor GT8.

For example, as illustrated by FIG. 5B, the fourth connection line 224 overlaps with the active layer GA7 of the first noise reduction transistor GT7, and the overlapping part of the fourth connection line 224 and the active layer GA7 of the first noise reduction transistor GT7 may serve as the gate of the first noise reduction transistor GT7.

For example, as illustrated by FIG. 5B, the fifth connection line 225 overlaps with the active layer GA6 of the second noise reduction transistor GT6, and the overlapping part of the fifth connection line 225 and the active layer GA6 of the second noise reduction transistor GT6 may serve as the gate of the second noise reduction transistor GT6.

For example, as illustrated by FIG. 5B, the first comb electrode 228 overlaps with the active layer GA5 of the output transistor GT5 to serve as the gate of the output transistor GT5, and the second comb electrode 229 overlaps with the active layer GA4 of the control transistor GT4 to serve as the gate of the control transistor GT4.

For example, as illustrated by FIG. 5B, the first electrode block 226 is connected with the active layer GA8 of the voltage stabilizing transistor GT8 and the gate of the output transistor GT5 to serve as the lower electrode plate of the second capacitor GC2.

For example, as illustrated by FIG. 5B, the second electrode block 227 is connected with the gate of the output control transistor GT4 to serve as the lower electrode plate of the first capacitor GC1.

FIG. 5C shows a conductive layer 230, which includes a third electrode block 231 and a fourth electrode block 232. The third electrode block 231 overlaps with the first electrode block 226 as the upper electrode plate of the second capacitor GC2, and the fourth electrode block 232 overlaps with the second electrode block 226 as the upper electrode plate of the first capacitor GC1.

FIG. 5C shows a conductive layer 230, which includes a third electrode block 231 and a fourth electrode block 232. The third electrode block 231 overlaps with the first electrode block 226 as the upper electrode plate of the second capacitor GC2, and the fourth electrode block 232 overlaps with the second electrode block 226 as the upper electrode plate of the first capacitor GC1.

FIG. 5D shows a plurality of vias V for connection between different layers of the gate driving unit, which will not be described in detail here.

FIG. 5E shows a first clock signal line GCK, a second clock signal line GCB, a start line 152, a first power line 153 and a second power line 154; the first connection line 221 is connected with the first clock signal line GCK, and the fourth connection line 224 is connected with the second clock signal line GCB.

For example, as illustrated by FIG. 5E, the output control transistor GT4, the output transistor GT5 and the voltage stabilizing transistor GT8 are located on one side of the second power line 154, and the input transistor GT1, the first control transistor GT2, the second control transistor GT3, the first noise reduction transistor GT7 and the second noise reduction transistor GT6 are located on the other side of the second power line 154.

For example, as illustrated by FIG. 5E, the second capacitor GC2 is located on one side of the second power line 154, and the first capacitor GC1 is located on the other side of the second power line 154.

It is worth noting that, unlike FIG. 4 and FIG. 5A-F ig. 5E, in order to clearly show the positions of the transistors and capacitors, the reference numerals of other transistors and capacitors in the gate driving unit 141 in FIG. 2 are omitted from the letter “G”.

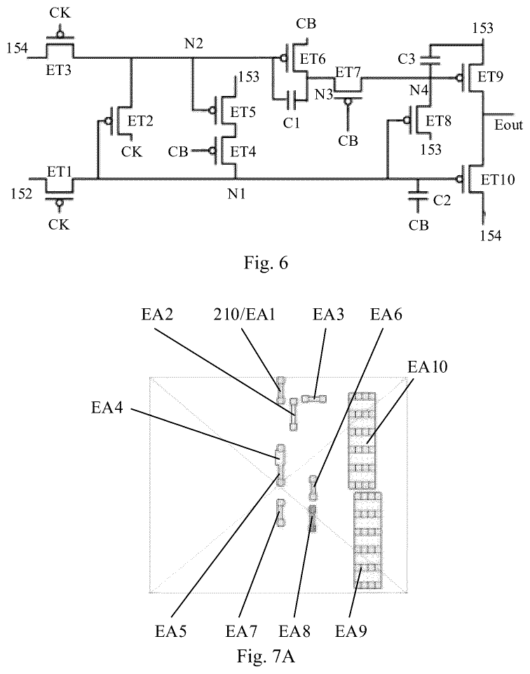

FIG. 6 is an equivalent schematic diagram of an emission control unit in a display panel provided by an embodiment of the present disclosure. As illustrated by FIG. 6, the light emitting control unit 142 includes a first transistor ET1 (also called input transistor), a second transistor ET2, a third transistor ET3, a fourth transistor ET4, a fifth transistor ET5, a sixth transistor ET6, a seventh transistor ET7, an eighth transistor ET8, a ninth transistor ET9, a tenth transistor ET10 (also called output transistor), a first capacitor EC1, a second capacitor EC2 and a third capacitor EC3. The light emitting control unit adopts 10T3C structure, although the embodiments of the present disclosure include but are not limited to this.

It should be noted that the above-mentioned light emitting control unit is a lighting emitting control shift register. When a plurality of lighting emitting control shift registers are cascaded, the second electrode of the first transistor ET1 in the first-stage lighting emitting control shift register can be connected with the input terminal, which is configured to be connected with the start line 152 to receive a trigger signal as an input signal. While the second electrode of the first transistor ET1 in other stages of the light emitting control shift register units is electrically connected with the output end of the previous stage of the light emitting control shift register unit to receive the output signal output from the output end OUT of the previous stage of light emitting control shift register unit as an input signal, thereby realizing shift output, for example, providing line-by-line shift light emission control signals to pixels arranged in an array in the display area of the display substrate.

As illustrated by FIG. 6, the gate of the first transistor ET1 is connected with the first clock signal line GCK to receive the first clock signal, the first electrode of the first transistor ET1 is connected with the first node N1, and the second electrode of the first transistor ET1 is connected with the input terminal. For example, when the light emitting control unit is the first-stage light emitting control unit, the input terminal is connected with the start line 152 to receive the trigger signal, and when the light emitting control unit is other light emitting control units at all levels except the first-stage light emitting control unit, the input terminal is connected with the output terminal OUT of the superior light emitting control unit.

As illustrated by FIG. 6, the second transistor ET2, the gate of the second transistor ET2 is connected with the first node N1, the first electrode of the second transistor ET2 is connected with the second node N2, and the second electrode of the second transistor ET2 is connected with the first clock signal line GCK to receive the first clock signal.

As illustrated by FIG. 6, the gate of the third transistor ET3 is connected with the first clock signal line GCK to receive the first clock signal, the first electrode of the third transistor ET3 is connected with the second node N2, and the second electrode of the third transistor ET3 is connected with the first power line 153 to receive the high-level voltage.

As illustrated by FIG. 6, the gate of the fourth transistor ET4 is connected with the second clock signal line GCB to receive the second clock signal, the first electrode of the fourth transistor ET4 is connected with the first node N1, and the second electrode of the fourth transistor ET4 is connected with the second electrode of the fifth transistor ET5.

As illustrated by FIG. 6, the gate of the fifth transistor ET5 is connected with the second node N2, and the first electrode of the fifth transistor ET5 is connected with the second power line 154 to receive the low-level signal.

As illustrated by FIG. 6, the first electrode of the sixth transistor ET6 is connected with the second clock signal line GCB to receive the second clock signal, and the second electrode of the sixth transistor ET6 is connected with the third node N3.

As illustrated by FIG. 6, the gate of the seventh transistor ET7 is connected with the second clock signal line GCB to receive the second clock signal, the first electrode of the seventh transistor ET7 is connected with the third node N3, and the second electrode of the seventh transistor ET7 is connected with the fourth node N4.

As illustrated by FIG. 6, the gate of the eighth transistor ET8 is connected with the first node N1, the first electrode of the eighth transistor ET8 is connected with the fourth node N4, and the second electrode of the eighth transistor ET8 is connected with the second power line 154 to receive the low-level signal.

As illustrated by FIG. 6, the gate of the ninth transistor ET9 is connected with the fourth node N4, the first electrode of the ninth transistor ET9 is connected with the second power line 154 to receive the low-level signal, and the second electrode of the ninth transistor ET9 is connected with the output terminal.

As illustrated by FIG. 6, the first electrode of the tenth transistor ET10 is connected with the first power line 153 to receive the high-level voltage, and the second electrode of the tenth transistor ET10 is connected with the output terminal.

As illustrated by FIG. 6, the second electrode of the first capacitor EC1 is connected with the third node N3; The second electrode of the second capacitor EC2 is connected with the second clock signal line GCB to receive the second clock signal; the first electrode of the third capacitor EC3 is connected with the fourth node N4, and the second electrode of the third capacitor EC3 is connected with the second power line 154 to receive the low-level signal.

It should be noted that the transistors in the light emitting control units shown in FIG. 6 are all described by taking P-type transistors as an example, that is, each transistor is turned on when the gate is connected with the low level (Conduction Level) and turned off when the gate is connected with the high level (Cut-off Level). In this case, the first electrode of the transistor may be the source and the second electrode of the transistor may be the drain. Of course, the embodiments of the present disclosure include but are not limited to this, and each transistor can also adopt an N-type transistor or a mix of a P-type transistor and an N-type transistor, as long as the port polarities of the selected transistors are simultaneously connected according to the port polarities of the corresponding transistors in the embodiments of the present disclosure. In addition, the working principle of the light emitting control unit can refer to the related introduction in this field, and will not be repeated here.

It should be noted that the transistors used in the light emitting control unit can all be thin film transistors or field effect transistors or other switching devices with the same characteristics. Here, all thin film transistors are taken as examples to explain. For example, the active layer (channel area) of the transistor is made of semiconductor materials, such as polysilicon (e.g. low-temperature polysilicon or high-temperature polysilicon), amorphous silicon, indium gallium zinc oxide (IGZO) and the gate, source and drain are made of metal materials, such as aluminum or aluminum alloy. The source and drain of the transistor used here can be symmetrical in structure, so there can be no difference in structure between the source and drain. In the embodiments of the present disclosure, in order to distinguish the two electrodes of the transistor except the gate, one of them is directly described as the first electrode and the other as the second pole. Furthermore, in the embodiments of the present disclosure, the electrodes of the capacitor may be metal electrodes or one of the electrodes may be semiconductor materials (e.g., doped polysilicon).

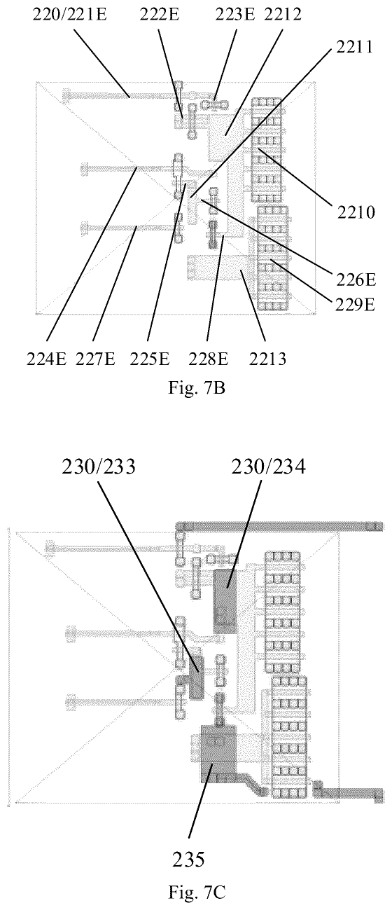

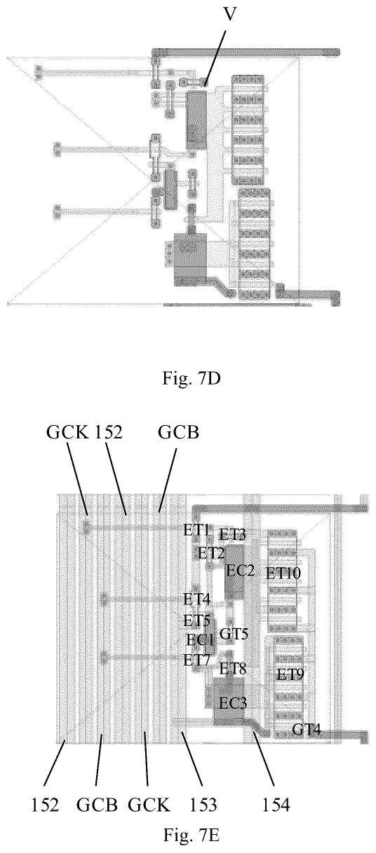

FIG. 7A-FIG. 7E are layout diagrams of the light emitting control unit in a display panel provided by an embodiment of the present disclosure.

FIG. 7A shows a semiconductor layer 210, which includes an active layer EA1 of a first transistor ET1, an active layer EA2 of a second transistor ET2, an active layer EA3 of a third transistor ET3, an active layer EA4 of a fourth transistor ET4, an active layer EA5 of a fifth transistor ET5, an active layer EA6 of a sixth transistor ET6, an active layer EA7 of a seventh transistor ET7, an active layer EA8 of an eighth transistor ET8, an active layer EA9 of a ninth transistor ET9, and an active layer EA10 of a tenth transistor ET10. The active layer EA10 of the tenth transistor ET10 has a larger channel width-length ratio, so that the leakage current can be reduced.

FIG. 7B shows the gate layer 220, which includes a sixth connection line 221E, a seventh connection line 222E, an eighth connection line 223E, a ninth connection line 224E, a tenth connection line 225E, an eleventh connection line 226E, a twelfth connection line 227E, a thirteenth connection line 228E, a third comb electrode 229E, a fourth comb electrode 2210, a fifth electrode block 2211, a sixth electrode block 2212, and a seventh electrode block 2213.

For example, as illustrated by FIG. 7B, the sixth connection line 221E overlaps with the active layer of the first transistor ET1, and the portion where the sixth connection line 221E overlaps with the active layer of the first transistor ET1 may serve as the gate of the first transistor ET1.

For example, as illustrated by FIG. 7B, the seventh connection line 222E overlaps with the active layer of the second transistor ET2, and the portion where the seventh connection line 222E overlaps with the active layer of the second transistor ET2 may serve as the gate of the second transistor ET2.

For example, as illustrated by FIG. 7B, the eighth connection line 223E overlaps with the active layer of the third transistor ET3, and the portion where the eighth connection line 223E overlaps with the active layer of the third transistor ET3 may serve as the gate of the zener transistor GT8.

For example, as illustrated by FIG. 7B, the ninth connection line 224E overlaps with the active layer of the fourth transistor ET4, and the portion where the ninth connection line 224E overlaps with the active layer of the fourth transistor ET4 may serve as the gate of the fourth transistor ET4.

For example, as illustrated by FIG. 7B, the tenth connection line 225E overlaps with the active layer of the fifth transistor ET5, and the portion where the tenth connection line 225E overlaps with the active layer of the fifth transistor ET5 may serve as the gate of the fifth transistor ET5.

For example, as illustrated by FIG. 7B, the eleventh connection line 226E overlaps with the active layer of the sixth transistor ET6, and the portion where the eleventh connection line 226E overlaps with the active layer of the sixth transistor ET6 may serve as the gate of the sixth transistor ET6.

For example, as illustrated by FIG. 7B, the twelfth connection line 227E overlaps with the active layer of the seventh transistor ET7, and the portion where the twelfth connection line 227E overlaps with the active layer of the seventh transistor ET7 may serve as the gate of the seventh transistor ET7.

For example, as illustrated by FIG. 7B, the thirteenth connection line 228E overlaps with the active layer of the eighth transistor ET8, and the portion where the thirteenth connection line 228E overlaps with the active layer of the eighth transistor ET8 may serve as the gate of the eighth transistor ET8.

For example, as illustrated by FIG. 7B, the third comb electrode 229E overlaps with the active layer of the ninth transistor ET9 to serve as the gate of the ninth transistor ET9, and the fourth comb electrode 2210 overlaps with the active layer of the tenth transistor ET10 to serve as the gate of the tenth transistor ET10.

For example, as illustrated by FIG. 7B, the fifth electrode block 2211 can serve as the lower electrode plate of the first capacitor EC1, the sixth electrode block 2212 can serve as the lower electrode plate of the second capacitor EC2, and the seventh electrode block 2213 can serve as the lower electrode plate of the third capacitor EC3.

FIG. 7C shows a conductive layer 230, which includes an upper electrode plate 233 of the first capacitor EC1, an upper electrode plate 234 of the second capacitor EC2, and an upper electrode plate 235 of the third capacitor EC3.

FIG. 7D shows a plurality of vias V for connection between different layers of the gate driving unit, which will not be described in detail here.

FIG. 7E shows the first clock signal line GCK, the second clock signal line GCB, the start line 152, the first power line 153 and the second power line 154; the sixth connection line 221E is connected with the first clock signal line GCK, and the ninth connection line 224E and the twelfth connection line 227E are connected with the second clock signal line GCB.

For example, as illustrated by FIG. 7E, the fourth transistor ET4, the ninth transistor ET9 and the tenth transistor ET10 are located on one side of the second power line 154, and the first transistor ET1, the second transistor ET2, the third transistor ET3, the fifth transistor ET5, the sixth transistor ET6, the seventh transistor ET7 and the eighth transistor ET8 are located on the other side of the second power line 154.

It is worth noting that, different from FIG. 6 and FIG. 7A-FIG. 7E, in order to show the positions of the transistors and capacitors more clearly, the reference numerals of other transistors and capacitors in the light emitting control unit 142 in FIG. 2 are omitted from the letter “E”.

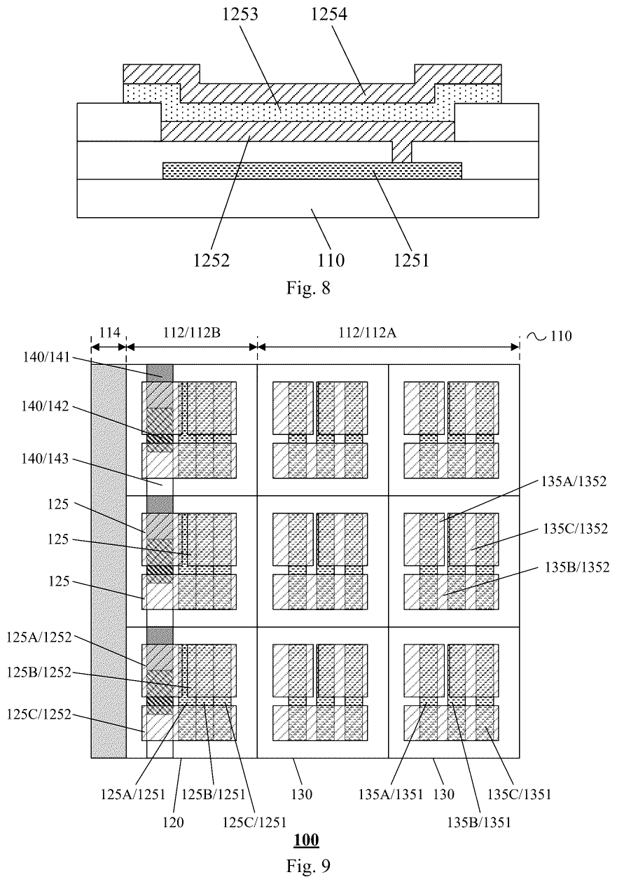

FIG. 8 is a schematic sectional view of an edge sub-pixel in a display panel provided by an embodiment of the present disclosure. As illustrated by FIG. 8, each edge sub-pixel 125 further includes an edge organic light emitting layer 1253 and a cathode 1254; the edge organic light emitting layer 1253 is located on the side of the anode 1252 away from the substrate 110. The cathode 1254 is located on the side of the edge organic light emitting layer 1253 away from the substrate 110. In other words, edge sub-pixels include organic light emitting diodes, which have the advantages of high contrast, wide viewing angle, fast response speed, lightness, thinness and so on.

In some examples, each middle sub-pixel further includes a middle organic light emitting layer and a cathode; the middle organic light emitting layer is located on one side of the anode away from the substrate; the cathode is located on the side of the edge organic light emitting layer away from the substrate. For the specific structure of the middle sub-pixel, please refer to the edge sub-pixel in FIG. 8.

In some examples, as illustrated by FIG. 8, the anode 1252 can be connected with the output end of the corresponding edge pixel driving circuit 1251 through a via hole, so that the edge organic light emitting layer 1253 can be driven to emit light by using the current output by the edge pixel driving circuit 1251. It should be noted that the driving circuit 1251 can be the drain of the light emitting control transistor.

In some examples, as illustrated by FIG. 8, one of the anode 1252 and the cathode 1254 may include a reflective layer, and the other may include a semi-transparent and semi-reflective layer, so that light extraction efficiency may be improved.

In some examples, the edge pixel driving circuit 1251 may include a plurality of transistors and at least one storage capacitor. For example, the edge pixel driving circuit may adopt 7T1C, 9T1C, 3T1C and other structures. It should be noted that the above “T” stands for transistor and “C” stands for capacitor.

In some examples, each edge sub-pixel may also include functional film layers such as electron injection layer, electron transport layer and hole blocking layer between the cathode and the edge organic light emitting layer, and functional film layers such as hole injection layer, hole transport layer and electron blocking layer between the anode and the edge organic light emitting layer. Similarly, each middle sub-pixel may also include functional film layers such as electron injection layer, electron transport layer and hole blocking layer between the cathode and the middle organic light emitting layer, and functional film layers such as hole injection layer, hole transport layer and electron blocking layer between the anode and the middle organic light emitting layer.

In some examples, the base substrate may be a rigid substrate such as a glass substrate, a plastic substrate, a quartz substrate, or a flexible substrate such as a polyimide substrate.

FIG. 9 is a schematic diagram of another display panel provided by an embodiment of the present disclosure. As illustrated by FIG. 9, the display panel 100 includes a substrate 110, an edge pixel group 120 and a row driving circuit 140. The base substrate 110 includes a display area 112 and a peripheral area 114; the edge pixel group 120 includes a plurality of edge sub-pixels 125; the display area 112 includes a middle display area 112A and an edge display area 112B located in the middle display area 112A close to the peripheral area 114. Each edge sub-pixel 125 includes an edge pixel driving circuit 1251 and an anode 1252 connected to the edge pixel driving circuit 1251, and the edge pixel driving circuit 1251 can provide a driving current to the anode 1252 to drive the light emitting layer on the anode 1252 to emit light.

As illustrated by FIG. 9, the edge pixel group 120 is located on the edge display area 112B, and the row driving circuit 140 is at least partially located on the edge display area 112B and overlaps with the anode 1252 of at least one edge sub-pixel 125 in the edge pixel group 120. That is, the orthographic projection of the row driving circuit 140 on the base substrate 110 overlaps with the orthographic projection of the anode 1252 of at least one edge sub-pixel 124 in the edge pixel group 120 on the base substrate 110.

In a common display panel, the Gate Driver on Array (GOA) technology can be used to integrate the row driving circuit in the peripheral area, so that the row driving circuit can directly provide row driving signals such as gate driving signals and light emitting control signals for the sub-pixel array without additional gate driving chips and corresponding binding structures, thus reducing the cost and the frame width. However, in this case, the row driving circuit itself will still occupy a certain width, and it is impossible to achieve an extremely narrow frame.

In the display panel provided by the embodiments of the present disclosure, by arranging the row driving circuit at least partially in the edge display area and overlapping with the anode of at least one edge sub-pixel in the edge pixel group, the display panel can arrange the row driving circuit at least partially under the display area without placing all the row driving circuits in the peripheral area, thereby reducing the width of the peripheral area.

In some examples, as illustrated by FIG. 9, the row driving circuit 140 includes a plurality of the gate driving units 141, which can provide gate driving signals to the edge pixel driving circuit and the middle pixel driving circuit, and the plurality of light emitting control units 142, which can provide light emitting control signals to the edge pixel driving circuit and the middle pixel driving circuit. A plurality of edge pixel driving circuits 1251 of a plurality of edge sub-pixels 125 in the edge pixel group 120 are arranged in the first direction, and the plurality of gate driving units 141 and the plurality of light emitting control units 142 are arranged in the second direction, which the second direction intersects with the first direction.

For example, the second direction may be perpendicular to the first direction, but the embodiments of the present disclosure include but are not limited to this.

Similarly, the display panel 100 also includes the clock signal line, the start line, the first power line and the second power line, which are configured to drive a row driving circuit; the plurality of gate driving units and the plurality of light emitting control units share at least one selected from a group consisting of the clock signal line, the start line, the first power line and the second power line.

In a common display panel, the row driving circuit needs to provide the gate driving signal and the emission driving signal to the pixel driving circuit in the display area, and the gate driving unit providing the gate driving signal and the light emitting control unit providing the light emitting control signal are arranged side by side, that is, arranged in the first direction, so the size in the first direction is larger. In the display panel provided by the embodiments of the present disclosure, by arranging the plurality of gate driving units and the plurality of light emitting control units in the second direction, the size of the row driving circuits of the display panel in the first direction can be reduced, so that all the row driving circuits can be arranged in the edge display area. Moreover, by sharing at least one selected from a group consisting of the clock signal line, the start line, the first power line and the second power line with the plurality of gate driving units and the plurality of light emitting control units, the width occupied by the row driving circuit and various driving lines of the display device can be further reduced, thereby further reducing the width of the peripheral area. Through the above various designs, the display panel has an extremely narrow frame. Furthermore, when the display panel provided by the embodiments of the present disclosure is used for splicing display, the spliced display device can realize seamless splicing and has excellent display effect.

In some examples, as illustrated by FIG. 9, the row driving circuit 140 further includes a dummy driving unit 143, which is not connected with the clock signal line 151, the start line 152 and the first power line 153, thereby not providing a row driving signal; the dummy driving unit 143, the plurality of gate driving units 141 and the plurality of light emitting control units 142 are arranged in the second direction.

In some examples, as illustrated by FIG. 9, the dummy driving unit 143 is inserted between the light emitting control unit 142 corresponding to one row of edge sub-pixels 120 and the gate driving unit 141 corresponding to the next row of edge sub-pixels 120.

In some examples, as illustrated by FIG. 9, the row driving circuits 140 are all located on the edge display area 112A, and the orthographic projection of the edge of the row driving circuits 140 away from the middle display area 112a on the substrate 110 overlaps with the orthographic projection of the anode 1252 of the outermost edge sub-pixel 125 in the edge pixel group 120 on the substrate 110. Therefore, the width of the peripheral area of the display panel can be minimized.

In some examples, as illustrated by FIG. 9, the display panel 100 further includes a middle pixel group 130 including a plurality of middle sub-pixels 135; the middle pixel group 130 is located in the middle display area 112A, and each middle sub-pixel 135 includes a middle pixel driving circuit 1351 and an anode 1352 connected to the middle pixel driving circuit 1351. The area occupied by a plurality of middle pixel driving circuits 1351 and a plurality of middle pixel driving circuits 1351 of a plurality of middle sub-pixels 135 in the middle pixel group 130 is larger than the area occupied by a plurality of edge pixel driving circuits 1251 and a plurality of edge pixel driving circuits 1251 of a plurality of edge sub-pixels 125 in the edge pixel group 120. Thus, by reducing the area between the edge pixel driving circuit and the edge pixel driving circuit of the display panel, the row driving circuit 140 can overlap with the anode 1252 of at least one edge sub-pixel 125 in the edge pixel group 120, thereby reducing the frame width.

It should be noted that the middle sub-pixel and the edge sub-pixel here are only different in position and some structures, and they are all sub-pixels used to display the same image; in some examples, the kind, color and size of light emitted by the middle sub-pixel and the edge sub-pixel are the same.

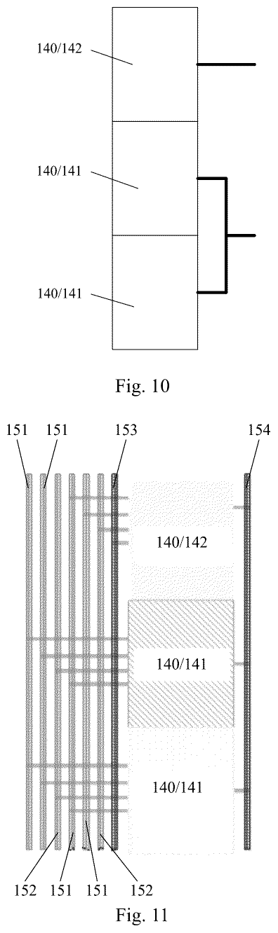

FIG. 10 is a schematic diagram of a row driving circuit in a display panel provided by an embodiment of the present disclosure. As illustrated by FIG. 10, the output terminals of two adjacent gate driving units 141 in the second direction are connected to provide gate driving signals for edge sub-pixels located in the same edge pixel group, thereby reducing the fluctuation of gate driving signals and stabilizing the input of data voltage.

FIG. 11 is a schematic diagram of signal line connection of a row driving circuit in a display panel provided by an embodiment of the present disclosure. As illustrated by FIG. 11, the plurality of gate driving units 141 and the plurality of light emitting control units 142 share at least one elected from a group consisting of the clock signal line 151, the start line 152, the first power line 153 and the second power line 154. Therefore, the number of the clock signal lines, the start lines, the first power lines and the second power lines of the display panel can be reduced, thereby further reducing the frame width.

In some examples, as illustrated by FIG. 11, the plurality of gate driving units 141 and the plurality of light emitting control units 142 share a clock signal line 151, a start line 152, a first power line 153 and a second power line 154, thereby minimizing the number of signal lines. Of course, the embodiments of the present disclosure include but are not limited to this, and the plurality of gate driving units 141 and the plurality of light emitting control units 142 may share only a part of the clock signal line 151, the start line 152, the first power line 153 and the second power line 154.

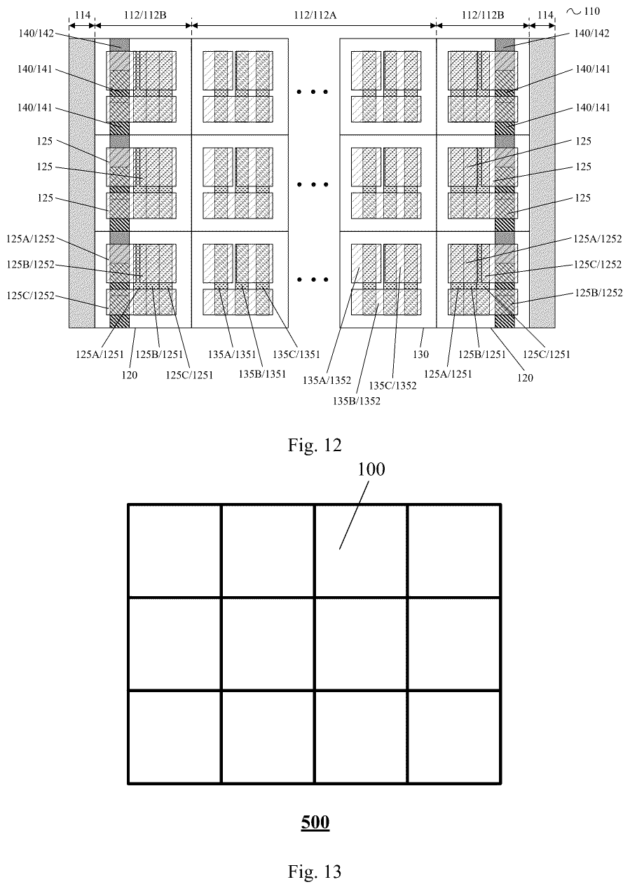

FIG. 12 is a schematic diagram of another display panel provided by an embodiment of the present disclosure. As illustrated by FIG. 12, the display panel 100 includes a substrate 110, an edge pixel group 120 and a row driving circuit 140. The base substrate 110 includes a display area 112 and a peripheral area 114; the edge pixel group 120 includes a plurality of edge sub-pixels 125; the display area 112 includes a middle display area 112A and two edge display areas 112B located at both sides of the middle display area 112A. Each edge sub-pixel 125 includes an edge pixel driving circuit 1251 and an anode 1252 connected to the edge pixel driving circuit 1251, and the edge pixel driving circuit 1251 can provide a driving current to the anode 1252 to drive the light emitting layer on the anode 1252 to emit light.

As illustrated by FIG. 12, two edge display areas 112B are respectively provided with edge sub-pixel groups 120, and row driving circuits 140 are respectively located in the two edge display areas 112B, thereby driving the sub-pixels in the display panel from both sides. The row driving circuit 140 overlaps the anode 1252 of at least one edge sub-pixel 125 in the edge pixel group 120; that is, the orthographic projection of the row driving circuit 140 on the base substrate 110 overlaps with the orthographic projection of the anode 1252 of at least one edge sub-pixel 124 in the edge pixel group 120 on the base substrate 110.

In the display panel provided by the embodiments of the present disclosure, by arranging the row driving circuit at least partially in the edge display area and overlapping with the anode of at least one edge sub-pixel in the edge pixel group, the row driving circuit of the display panel can be arranged at least partially under the display area without placing all the row driving circuits in the peripheral area, so that the width of the peripheral area can be reduced, thereby reducing the border width of the display panel and realizing an extremely narrow frame. Furthermore, when the display panel provided by the embodiments of the present disclosure is used for splicing display, the spliced display device can realize seamless splicing and has excellent display effect.

It should be noted that these two row driving circuits 140 can drive the same row of sub-pixels at the same time, or one of them can drive odd rows of sub-pixels and the other can drive even rows of sub-pixels.

In some examples, as illustrated by FIG. 12, the row driving circuit 140 includes a plurality of gate driving units 141, which can provide gate driving signals to the edge pixel driving circuit and the middle pixel driving circuit, and the plurality of light emitting control units 142, which can provide light emitting control signals to the edge pixel driving circuit and the middle pixel driving circuit. The plurality of gate driving units 141 and the plurality of light emitting control units 142 are arranged in the second direction, and the second direction intersects with the first direction.

Similarly, the display panel 100 also includes the clock signal line, the start line, the first power line and the second power line, which are configured to drive a row driving circuit; the plurality of gate driving units and the plurality of light emitting control units share at least one elected from a group consisting of the clock signal line, the start line, the first power line and the second power line. Therefore, the size of the row driving circuits of the display panel in the first direction can be reduced, so that all the row driving circuits can be arranged in the edge display area. Moreover, by sharing at least one selected from a group consisting of the clock signal line, the start line, the first power line and the second power line with the plurality of gate driving units and the plurality of light emitting control units, the width occupied by the row driving circuit and various driving lines of the display device can be further reduced, thereby further reducing the width of the peripheral area. Through the above various designs, the display panel has an extremely narrow frame. Furthermore, when the display panel provided by the embodiments of the present disclosure is used for splicing display, the spliced display device can realize seamless splicing and has excellent display effect.

At least one embodiment of the present disclosure also provides a display device. FIG. 13 is a schematic diagram of a display device provided by an embodiment of the present disclosure. As illustrated by FIG. 13, the display device 500 includes a display panel 100. Therefore, the display device can combine a plurality of display panels into a large-size and high-resolution display device by splicing. Moreover, because the display panel has an extremely narrow frame, the display device can realize seamless splicing, thereby providing excellent display effect.

In some examples, as illustrated by FIG. 13, the display device 500 includes a plurality of display panels 100 spliced with each other.

The following points need to be explained:
(1) In the drawings of the embodiment of this application, only the structures related to the embodiment of this application are involved, and other structures can refer to the general design.
(2) In case of no conflict, features in the same embodiment and different embodiments of the application can be combined with each other.

The above is only the specific implementation of this application, but the protection scope of this application is not limited to this. Any person familiar with this technical field can easily think of changes or substitutions within the technical scope disclosed in this application, which should be covered by this application. Therefore, the protection scope of this application should be based on the protection scope of the claims.

1. A display device, comprising a plurality of display panels mutually spliced, wherein each of a plurality of display panels comprises:
a base substrate, comprising a display area and a peripheral area;
an edge pixel group, comprising a plurality of edge sub-pixels; and
a row driving circuit, comprising a plurality of gate driving units and a plurality of light emitting control units,
wherein the display area comprises a middle display area and an edge display area located at a side of the middle display area close to the peripheral area, and each of a plurality of edge sub-pixels comprises an edge pixel driving circuit and an anode connected with the edge pixel driving circuit;
the edge pixel group is located in the edge display area, and the row driving circuit is at least partially located in the edge display area and overlaps with the anode of at least one edge among a plurality of edge sub-pixels in the edge pixel group,
a plurality of the edge pixel driving circuits of a plurality of edge sub-pixels in the edge pixel group are arranged in a first direction, the plurality of gate driving units and the plurality of light emitting control units are arranged in a second direction, and the second direction intersects with the first direction,
the display panel further includes a clock signal line, a start line, a first power line and a second power line that are configured to drive the row driving circuit, and the plurality of gate driving units and the plurality of light emitting control units share at least one selected from a group consisting of the clock signal line, the start line, the first power line and the second power line.

2. The display device according to claim 1, wherein each gate driving unit of the plurality of gate driving units comprises an output transistor and an input transistor, each light emitting control unit of the plurality of light emitting control units comprises an output transistor and an input transistor, the second power line extends in the second direction and passes through the plurality of gate driving units and the plurality of light emitting control units, and the plurality of gate driving units and the plurality of light emitting control units share the second power line,
the output transistor of the each gate driving unit and the output transistor of the each light emitting control unit are at a first side of the second power line in the first direction, and the input transistor of the each gate driving unit and the input transistor of the each light emitting control unit are at a second side of the second power line in the first direction.

3. The display device as claimed in claim 2, wherein the clock signal line, the start line and the first power line are at a side of both the input transistor of the each gate driving unit and the input transistor of the each light emitting control unit away from the second power line.

4. The display device according to claim 2, wherein the second power line is located in the edge display area, and overlaps with the anode of at least one edge sub-pixel of a plurality of edge sub-pixels in the edge pixel group.

5. The display device according to claim 2, wherein the clock signal line, the start line and the first power line are located in the edge display area, and overlap with the anode of at least one edge sub-pixel of a plurality of edge sub-pixels in the edge pixel group.

6. The display device according to claim 1, wherein output terminals of two gate driving units adjacent in the second direction of the plurality of gate driving units are connected, to provide gate driving signals for the edge sub-pixels in a same row in a same edge pixel group.

7. The display device according to claim 6, wherein two of the gate driving units are arranged between two adjacent light emitting control units among the plurality of light emitting control units.

8. The display device according to claim 1, wherein the row driving circuit further comprises a dummy driving unit which is not connected with all the clock signal line, the start line and the first power line,
the dummy driving unit, the plurality of gate driving units and the plurality of light emitting control units are arranged in the second direction.

9. The display device according to claim 8, wherein the dummy driving unit is inserted between the light emitting control unit corresponding to one row of the edge sub-pixels and the gate driving unit corresponding to the next row of the edge sub-pixels.

10. The display device according to claim 1, wherein the peripheral area, the edge display area and the middle display area are arranged in a first direction; in the edge pixel group, a size of the plurality of edge pixel driving circuits of the plurality of edge sub-pixels in the first direction is smaller than a size of a plurality of the anodes of the plurality of edge sub-pixels in the first direction.

11. The display device according to claim 1, wherein all the row driving circuit is located in the edge display area, and an orthographic projection of an edge of the row driving circuit away from the middle display area on the base substrate overlaps with an orthographic projection of the anode of an outermost edge sub-pixel among a plurality of edge sub-pixels in the edge pixel group on the base substrate.

12. The display device according to claim 1, further comprising:
a middle pixel group, comprising a plurality of middle sub-pixels,
wherein the middle pixel group is located in the middle display area, and each middle sub-pixel among a plurality of middle sub-pixels comprises a middle pixel driving circuit and an anode connected with the middle pixel driving circuit;
an area occupied by a plurality of the middle pixel driving circuits and intervals between the plurality of the middle pixel driving circuits of a plurality of middle sub-pixels in the middle pixel group is larger than an area occupied by a plurality of edge pixel driving circuits and intervals between the plurality of the edge pixel driving circuits of a plurality of edge sub-pixels in the edge pixel group.

13. The display device according to claim 12, wherein an area occupied by the intervals between a plurality of middle pixel driving circuits of a plurality of middle sub-pixels in the middle pixel group is larger than an area occupied by the intervals between a plurality of edge pixel driving circuits of a plurality of edge sub-pixels in the edge pixel group.

14. The display device according to claim 12, wherein the edge pixel group comprises a first edge sub-pixel, a second edge sub-pixel and a third edge sub-pixel, and the middle pixel group comprises a first middle sub-pixel, a second middle sub-pixel and a third middle sub-pixel;
the first edge sub-pixel and the first middle sub-pixel are configured to emit light of a first color, the second edge sub-pixel and the second middle sub-pixel are configured to emit light of a second color, and the third edge sub-pixel and the third middle sub-pixel are configured to emit light of a third color.

15. The display device according to claim 14, wherein a size of the anode of the first edge sub-pixel is the same as a size of the anode of the first middle sub-pixel, a size of the anode of the second edge sub-pixel is the same as a size of the anode of the second middle sub-pixel, and a size of the anode of the third edge sub-pixel is the same as a size of the anode of the third middle sub-pixel.

16. The display device according to claim 1, wherein the row driving circuit is located at a side of a plurality of edge pixel driving circuits in the edge pixel group away from the middle display area.

17. The display device according to claim 1, wherein each edge sub-pixel further comprises:
an edge organic light emitting layer, located at a side of the anode away from the base substrate; and
a cathode, located at a side of the edge organic light emitting layer away from the base substrate.

18. A display panel, comprising:
a base substrate, comprising a display area and a peripheral area;
an edge pixel group, comprising a plurality of edge sub-pixels; and
a row driving circuit, comprising a plurality of gate driving units and a plurality of light emitting control units,
wherein the display area comprises a middle display area and an edge display area located at a side of the middle display area close to the peripheral area, and each of a plurality of edge sub-pixels comprises an edge pixel driving circuit and an anode connected with the edge pixel driving circuit;
the edge pixel group is in the edge display area, and the row driving circuit is at least partially located in the edge display area and overlaps with the anode of at least one edge sub-pixel in the edge pixel group,
a plurality of the edge pixel driving circuits of a plurality of edge sub-pixels in the edge pixel group are arranged in a first direction, the plurality of gate driving units and the plurality of light emitting control units are arranged in a second direction, and the second direction is perpendicular to the first direction,
the display panel further includes a clock signal line, a start line, a first power line and a second power line that are configured to drive the row driving circuit, and the plurality of gate driving units and the plurality of light emitting control units share at least one selected from a group consisting of the clock signal line, the start line, the first power line and the second power line.

19. The display panel according to claim 18, wherein each gate driving unit of the plurality of gate driving units comprises an output transistor and an input transistor, each light emitting control unit of the plurality of light emitting control units comprises an output transistor and an input transistor, the second power line extends in the second direction and passes through the plurality of gate driving units and the plurality of light emitting control units, and the plurality of gate driving units and the plurality of light emitting control units share the second power line,
the output transistor of the each gate driving unit and the output transistor of the each light emitting control unit are at a first side of the second power line in the first direction, and the input transistor of the each gate driving unit and the input transistor of the each light emitting control unit are at a second side of the second power line in the first direction.

20. The display panel according to claim 19, wherein the clock signal line, the start line and the first power line are at a side of both the input transistor of the each gate driving unit and the input transistor of the each light emitting control unit away from the second power line.

21.-22. (canceled)
